(19) United States
(12) Patent Application Publication
(10) Pub. No.: US 2026/0371471 A1
(43) Pub. Date: Nov. 19, 2026

(54) SYSTEM FOR AND METHOD OF MANAGING BYPRODUCT ACCUMULATION IN A RADIATION SOURCE

(71) Applicant: ASML Netherlands B.V., Veldhoven (NL)

(72) Inventors: Armin Bernhard Ridinger, San Diego, CA (US); Kyle John Scaffidi, San Diego, CA (US)

(21) Appl. No.: 19/475,601

(22) PCT Filed: Apr. 23, 2024
(86) PCT No.: PCT/EP2024/061117

§ 371 Date: Oct. 15, 2025

Related U.S. Application Data
(60) Provisional application No. 63/468,607, filed on May 24, 2023.

(51) Int. Cl. H05G 2/00

(52) U.S. Cl. CPC H05G 2/0094

(57) ABSTRACT

A system and method of reducing byproduct accumulating on a surface in a scrubber of a radiation source are provided. The system and method provide for cycling a temperature of the surface above and below a melting temperature of a target material or for controlling a temperature profile of the surface so that only part of the surface is heated above the melting temperature of the target material at one time.

### CROSS-REFERENCE TO RELATED APPLICATIONS

This application claims priority to U.S. Application No. 63/468,607, filed May 24, 2023, titled SYSTEM FOR AND METHOD OF MANAGING TARGET MATERIAL ACCUMULATION IN AN EUV RADIATION SOURCE, which is incorporated herein in its entirety by reference.

### FIELD

The disclosed subject matter relates to a system for and method of managing accumulation of target material in an extreme ultraviolet radiation source.

### BACKGROUND

Extreme ultraviolet (“EUV”) radiation, e.g., electromagnetic radiation having a wavelength of around 50 nm or less (also sometimes referred to as soft x-rays), including radiation at a wavelength of about 13.5 nm, can be used in photolithography processes to produce extremely small features in substrates such as silicon wafers. Here and elsewhere herein the term “light” is sometimes used to refer to EUV radiation with the understanding that the radiation described using that term is not in the visible part of the spectrum.

Methods for generating EUV radiation include converting a target material to a plasma state at an irradiation site in a vacuum vessel or chamber. The target material preferably includes at least one element, e.g., xenon, lithium, or tin, with one or more emission lines in the EUV portion of the electromagnetic spectrum. The target material can be solid, liquid, or gas. In one such method, often termed laser produced plasma (“LPP”), the required plasma can be produced by using a laser beam to irradiate a target material having the required line-emitting element. One LPP technique involves generating a stream of target material droplets and irradiating at least some of the droplets with one or more laser radiation pulses. The resulting EUV radiation is collected by collection optics located within the chamber which at EUV wavelengths are generally reflective.

LPP generation of EUV radiation produces irradiation byproducts made up of or containing target material including particulate target material debris, and target material vapor, target material radicals, and compounds including target material. For example, when the target material is tin, the irradiation byproducts may include particles or clusters of tin debris, tin vapor, and stannane (SnH4) produced when the tin reacts with hydrogen radicals.

One challenge in operating an EUV radiation source such as that described is management of these irradiation byproducts, i.e., preventing the irradiation byproducts from degrading operation of the source, for example, by reducing the reflectivity of the collection optics. For example, one method of controlling these irradiation byproducts involves introducing a carrier gas into the chamber which entrains the irradiation byproducts including the target material vapor. In some systems molecular hydrogen (H2) gas at pressures in the range of about 0.5 to about 3 mbar is used in the vacuum chamber for debris mitigation. Hydrogen is relatively transparent to EUV radiation having a wavelength of about 13.5 nm. H2 gas is introduced into the vacuum chamber to slow down the energetic debris (ions, atoms, and clusters) of target material created by the plasma by collisions with the gas molecules. For this purpose a flow of H2 gas is used which may also be counter to the debris trajectory. This serves to reduce the damage of deposition, implantation, and sputtering of target material on the optical coating of the collector.

The carrier gas containing the target material irradiation byproducts carries the target material irradiation byproducts out of the chamber through an exhaust system. The target material irradiation byproducts, however, can deposit target material on every surface in the exhaust path of the carrier gas/target material mixture. For example, if the carrier gas with target material-containing vapor is pumped via the top of the vessel to vacuum pumps through a scrubber, then target material can deposit and accumulate on all of the surfaces upstream of, in, and downstream of the scrubber. This accumulated target material can drop onto EUV light-collection optics in the chamber and damage vacuum pumps or clog the exhaust paths. Also the accumulation of target material inside the scrubber can lead to a high pressure drop across the scrubber in turn contributing to process variation.

Further complicating matters, the liquid target material typically flows other than as intended or desired. For example, structures within the chamber such as vanes and a gutter for a scrubber provided to remove some or all of the target material vapor in the chamber may drip liquid target material onto the collector. Also the scrubber gutter may overflow and liquid target material may run down the back of the vanes creating a thermal short (i.e., an unintended heat conductive path) and clogging the flow path to the capture receptacle. The flow restriction caused by target material accumulation leads to the gas finding a path through smaller spaces in the vanes and collector causing significantly increased collector degradation by target material deposition.

One technique for controlling target material accumulation involves capturing target material on a surface heated to above the melting point of the target material. There the target material melts (or remains molten) and is caused to flow to a capture receptacle. One potential issue with this technique arises with a target material such as tin which, when molten, tends to erupt or “spit” in the presence of hydrogen radicals such as are found in an EUV chamber. This ejected target material can strike and damage or contaminate the collection optics.

It would thus be advantageous to improve the management of target material accumulation in an EUV radiation source. It is in this context that the need for the subject matter of the present disclosure arises.

### SUMMARY

The following presents a succinct summary of one or more embodiments in order to promote a basic understanding of the presently disclosed subject matter. This summary is not an extensive overview of all contemplated embodiments and is not intended to identify as key or critical any elements of any embodiments nor delineate the scope of any or all embodiments. Its sole purpose is to present some concepts relating to one or more embodiments in a streamlined form as a prelude to the more detailed description that is presented later.

According to an aspect of an embodiment there is disclosed an exhaust system in which target material accumulation is managed using a multi-zone drip-off heat-cycled procedure that minimizes process variation by eliminating the temporary very high pressure drop penalty incurred by use of a contaminated exhaust system component. According to another aspect of an embodiment there is disclosed a vessel wall drip-off scheme to help minimize process variation via elimination of a gas temperature change which reduces EUV gas transmission variation, with the potential to reduce local maximum temperatures to be above but very close to the temperature needed for target material melting during drip-off (the temperature at which the spitting rate of molten tin is lowest) or to shape the path that molten target material takes during a drip off.

According to another aspect of an embodiment there is disclosed a system for management of a target material in an extreme ultraviolet radiation source, the system comprising at least one surface arranged such that a carrier gas entraining target material vapor and debris flows over the surface thus leaving deposited target material on the surface, at least one heating element in thermal communication with the at least one surface, and a controller configured to control the at least one heating element to cycle the at least one heating element between a first state in which a temperature of the at least one surface is above a melting temperature of the target material and a second state in which a temperature of the at least one surface is below the melting temperature of the target material.

The at least one surface may comprise a surface in an exhaust system for the extreme ultraviolet radiation source. The at least one surface may comprise a surface in a scrubber. The exhaust system may include a scrubber and the at least one surface may be positioned outside of the scrubber with respect to a flow of the carrier gas entraining the vapor. The at least one surface may comprise a surface in a vacuum vessel for the extreme ultraviolet radiation source.

The target material may comprise tin. The carrier gas may comprise molecular hydrogen.

According to another aspect of an embodiment there is disclosed a system for management of a target material in an extreme ultraviolet radiation source, the system comprising at least one surface arranged such that a carrier gas entraining target material vapor and debris flows over the surface thus leaving deposited target material on the surface, the surface having at least a first zone and a second zone, a first heating element in thermal communication with the first zone, a second heating element in thermal communication with the second zone and a controller configured to control the first heating element and the second heating element to cycle between a first state in which a temperature of the first zone is above a melting temperature of the target material and the temperature of the second zone is below a melting temperature of the target material and a second state in which a temperature of the first zone is below the melting temperature of the target material and the temperature of the second zone is above the melting temperature of the target material.

The at least one surface may comprise a surface in an exhaust system for the extreme ultraviolet radiation source. The at least one surface may comprise a surface in a scrubber. The exhaust system may include a scrubber and the at least one surface may be positioned upstream of the scrubber with respect to a flow of the carrier gas entraining the vapor. The at least one surface may comprise a surface in a vacuum vessel for the extreme ultraviolet radiation source.

The target material may comprise tin. The carrier gas may comprise molecular hydrogen.

The controller may control the first heating element to lessen a variation in a time average of the temperature of the first zone and controls the second heating element to lessen a time average of the temperature of the second zone.

According to another aspect of an embodiment there is disclosed a system for management of a target material in an extreme ultraviolet radiation source, the system comprising at least one surface arranged such that a carrier gas entraining target material irradiation byproducts flows over the at least one surface thus depositing target material on the at least one surface, the at least one surface having a plurality of zones numbering N zones, N being a positive integer, a plurality of heating elements having at least N heating elements, each of the heating elements being in thermal communication with a respective one of the zones and each of the heating elements being controllable to heat its respective zone to a temperature above a melting temperature of the target material, and a controller configured to control each heating element in the plurality of heating elements such that only a subset of the zones numbering M zones may be heated above the melting temperature of the target material at any time, M being an integer less than N.

N may be five and M may be one. The plurality of zones may be arranged as a linear array and the controller may be configured to control the heating elements to cyclically heat the zones.

The at least one surface may comprise a surface in a scrubber. The exhaust system may include a scrubber and the at least one surface may be positioned outside of the scrubber with respect to a flow of the carrier gas entraining the vapor.

The target material may comprise tin. The carrier gas may comprise molecular hydrogen.

The controller may control each of the plurality of heating elements to lessen a variation in a time average of the temperature of a respective one of the plurality of zones.

According to another aspect of an embodiment there is disclosed a method of operating a scrubbing surface to remove target material deposits, the method comprising (a) maintaining the scrubbing surface at a first temperature below a melting temperature of the target material deposits to cause the target material deposits to accumulate on the scrubbing surface until a volume of target material deposits reaches a first amount causing a first degree of exhaust path restriction, (b) heating the scrubbing surface to a second temperature above the melting temperature of the target material deposits such that at least a portion of the volume of target material deposits on the scrubbing surface melts and flows away from the scrubbing surface to reduce the volume of target material deposits on the scrubbing surface, and (c) after a volume of target material deposits remaining on the scrubbing surface has been reduced below a second amount causing a second degree of exhaust path restriction, the second degree being less than the first degree, discontinuing heating the scrubbing surface to the second temperature and reverting to step (a).

The scrubbing surface may have multiple zones that are independently temperature controlled, the method further comprising cycling a temperature of the zones to alternately increase and decrease the temperatures of different zones at different times.

According to another aspect of an embodiment there is disclosed a method of controlling target material accumulation in an extreme ultraviolet radiation source, the method comprising flowing a mixture of a carrier gas and target material irradiation byproducts over at least one surface to deposit the target material on the surface and controlling at least one heating element in thermal communication with the at least one surface to repeatedly cycle the at least one heating element between a first state in which a temperature of the at least one surface is above a melting temperature of the target material and a second state in which a temperature of the at least one surface is below the melting temperature of the target material.

Controlling at least one heating element may comprise controlling a first heating element in thermal communication with a first zone of the at least one surface and a second heating element in thermal communication with a first zone of the at least one surface to cycle between a first state in which a temperature of the first zone is above a melting temperature of the target material and the temperature of the second zone is below a melting temperature of the target material and a second state in which a temperature of the first zone is below the melting temperature of the target material and the temperature of the second zone is above the melting temperature of the target material.

According to another aspect of an embodiment there is disclosed a method of controlling target material accumulation in an extreme ultraviolet radiation source, the method comprising flowing a mixture of a carrier gas and a target material vapor and debris over at least one surface to deposit the target material on a surface, the surface having a plurality of zones numbering N zones, and controlling each heating element of a plurality of heating elements having at least N heating elements each being in thermal communication with a respective one of the zones such that only a subset of the zones numbering M zones is heated above the melting temperature of the target material at any time, M being an integer less than N.

Further embodiments, features, and advantages of the subject matter of the present disclosure, as well as the structure and operation of the various embodiments, are described in detail below with reference to the accompanying drawings.

### BRIEF DESCRIPTION OF THE DRAWINGS

The accompanying drawings, which are incorporated herein and form part of the specification, illustrate the presently disclosed subject matter and, together with the description, further serve to explain the principles of the presently disclosed subject matter and to enable a person skilled in the relevant art(s) to make and use the presently disclosed subject matter.

FIG. 1 is a functional block diagram, not to scale, of an overall broad conception of a photolithography system.

FIG. 2 is a functional block diagram, not to scale, of a vacuum chamber and exhaust system of an EUV radiation source.

FIG. 3 is a diagram of a temperature-controlled surface in an EUV radiation source.

FIG. 4 is a graph of temperature as a function of time for a temperature-controlled surface in an EUV radiation source.

FIG. 5 is a graph of temperature as a function of time for a temperature-controlled surface in an EUV radiation source according to an aspect of an embodiment.

FIG. 6A is a diagram of a multizonal temperature-controlled surface in an EUV radiation source according to an aspect of an embodiment.

FIG. 6B is a diagram of a multizonal temperature-controlled surface in an EUV radiation source according to an aspect of an embodiment.

FIGS. 7A-7E are graphs of temperature as a function of time for the multizonal temperature-controlled surface in an EUV radiation source of FIG. 6A or 6B according to an aspect of an embodiment.

FIG. 8 is a graph of temperature as a function of time for the multizonal temperature-controlled surface in an EUV radiation source of FIG. 6A or 6B according to an aspect of an embodiment.

FIG. 9 is a flow chart of a process for managing target material in an EUV radiation source according to an aspect of an embodiment.

FIG. 10 is a flow chart of a process for managing target material in an EUV radiation source according to an aspect of an embodiment.

FIG. 11 is a flow chart of a process for managing target material in an EUV radiation source according to an aspect of an embodiment.

FIGS. 12A-12C are charts showing temperature control patterns for a multizonal temperature-controlled surface in an exhaust system of an EUV radiation source according to an aspect of an embodiment.

FIG. 13 is a chart showing an example of operational parameters for a multizonal temperature-controlled surface in an exhaust system of an EUV radiation source according to an aspect of an embodiment.

Further features and advantages of the presently disclosed subject matter, as well as the structure and operation of various embodiments of the presently disclosed subject matter, are described in detail below with reference to the accompanying drawings. It is noted that the scope of the presently disclosed subject matter is not limited to the specific embodiments described herein. Such embodiments are presented herein for illustrative purposes only. Additional embodiments will be apparent to persons skilled in the relevant art based on the teachings presented herein.

### DETAILED DESCRIPTION

Various embodiments are now described with reference to the drawings, wherein like reference numerals are used to refer to like elements throughout. In the following description, for purposes of explanation, numerous specific details are set forth in order to promote a thorough understanding of one or more embodiments. It may be evident in some or all instances, however, that any embodiment described below can be practiced without adopting the specific design details associated with it below. In other instances, well-known structures and devices are shown in block diagram form in order to facilitate description of one or more embodiments.

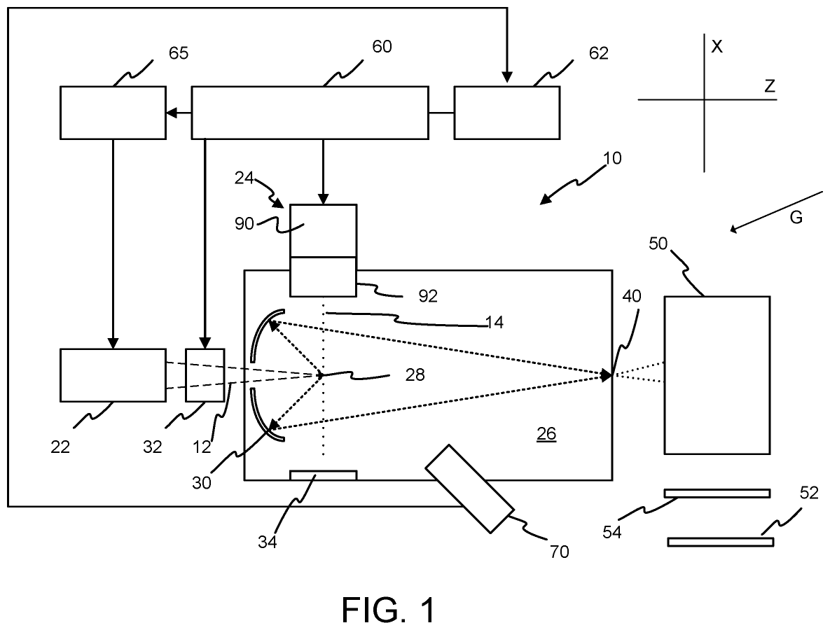

FIG. 1 is a functional block diagram of an example of an EUV radiation source, specifically, a laser produced plasma EUV radiation source 10. As shown, the EUV radiation source 10 may include a pulsed or continuous laser source 22, which may for example be a pulsed gas discharge CO2 laser source producing a beam 12 of radiation at 10.6 μm or 1 μm. The pulsed gas discharge CO2 laser source may have DC or RF excitation operating at high power and at a high pulse repetition rate.

The EUV radiation source 10 also includes a target delivery system 24 for delivering target material in the form of liquid droplets or a continuous liquid stream into an interior of a vessel or chamber 26. In this example, the target material is a liquid, but it could also be a solid or gas. The target material may be made up of tin or a tin compound, although other materials could be used. In the system depicted the target material delivery system 24 introduces droplets 14 of the target material into the interior of the chamber 26 to an irradiation region 28 where the target material may be irradiated to produce plasma. The EUV light source may also include a beam steering system 32.

In the system shown, the components are arranged so that the droplets 14 travel substantially horizontally. The direction from the laser source 22 towards the irradiation region 28, that is, the nominal direction of propagation of the beam 12, may be taken as the Z axis. The path the droplets 14 take from the target material delivery system 24 to the irradiation region 28 may be taken as the X axis. The view of FIG. 1 is thus normal to the XZ plane. The orientation of the EUV radiation source 10 may be rotated with respect to gravity as shown, with the arrow G showing the orientation with respect to gravitationally down. This orientation applies to the EUV radiation source but not necessarily to optically downstream components such as a scanner and the like. Also, while a system in which the droplets 14 travel substantially horizontally is depicted, it will be understood by one having ordinary skill in the art that other arrangements can be used in which the droplets travel vertically or at some angle with respect to gravity between and including 90 degrees (horizontal) and 0 degrees (vertical).

The EUV radiation source 10 may also include an EUV light source controller system 60 and a laser firing control system 65. The EUV radiation source 10 may also include a detector such as a target position detection system 70 that generates an output indicative of the absolute or relative position of a target droplet, e.g., relative to the irradiation region 28, and provide this output to a target position detection feedback system 62.

As shown in FIG. 1, the target material delivery system 24 may include a target delivery control system 90. The target delivery control system 90 is operable in response to a signal provided by the system controller 60 to adjust paths of the target droplets 14 through the irradiation region 28. This may be accomplished, for example, by repositioning the point at which a droplet generator 92 releases the target droplets 14. The droplet release point may be repositioned, for example, by tilting or by laterally translating the droplet generator 92. The droplet generator 92 extends into the chamber 26 and is preferably externally supplied with target material as well as with gas from a gas source to place the target material in droplet generator 92 under pressure. Droplets 14 that pass through the irradiation region 28 without being irradiated continue to a target material catcher 34.

Continuing with FIG. 1, the radiation source 10 may also include collection optics made up of one or more optical elements. In the following description, a collector 30 is used as an example of such an optical element, but the elucidated principles apply to other optical elements that may be present instead or as well. The collector 30 may be a normal incidence reflector, for example, implemented as a multilayer mirror (“MLM”) with additional thin barrier layers, for example B4C, Zork, Si3N4 or C, deposited at each interface to effectively block thermally-induced interlayer diffusion. Other substrate materials, such as aluminum (Al) or silicon (Si), can alternatively or also be used. The collector 30 may be in the form of a prolate ellipsoid, with a central aperture to allow the laser radiation 12 to pass through and reach the irradiation region 28. The collector 30 has a first focus at the irradiation region 28 and a second focus at an intermediate focus 40 where the EUV radiation may be output from the EUV radiation source 10 and input to, e.g., an integrated circuit lithography scanner 50 which uses the radiation, for example, to process a silicon wafer workpiece 52 in a known manner using a reticle or mask 54. The silicon wafer workpiece 52 is then additionally processed in a known manner to obtain an integrated circuit device.

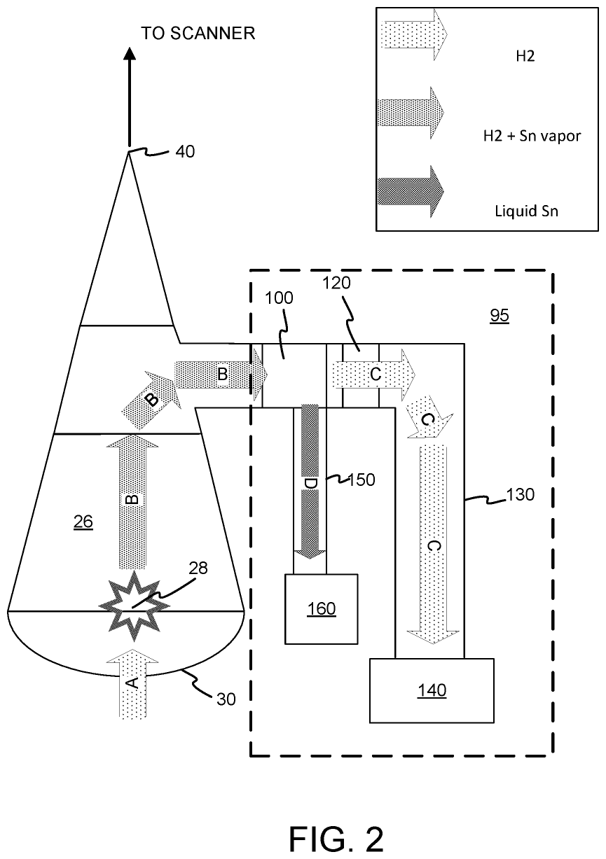

As mentioned, successful target material management is a critical technical challenge in an LPP EUV radiation source such as that just described. The conversion of the target material as part of generating EUV radiation also produces various target material irradiation byproducts in the form of target material debris, target material vapor, compounds containing the target material, and the like. These target material irradiation byproducts have a tendency to deposit target material on the walls of the chamber 26 and on surfaces in the exhaust system 95 (FIG. 2). This target material can detach from those surfaces and fall and contaminate the collection optics. The target material can also block various ports, conduits, and orifices.

In the description that follows tin is used as a nonlimiting example of a target material and tin vapor is used as a nonlimiting example of a target material irradiation byproduct but one of ordinary skill in the art will appreciate that the description applies to other possible target materials and other target material irradiation byproducts.

Thus, to control deposition of tin from tin vapor, a flow of carrier gas, for example H2, is introduced into the chamber 26 to establish a flow away from the collection optics and so to transport target material irradiation byproducts away from the collection optics and out of the chamber 26 through an exhaust system. This is depicted in FIG. 2, which shows a general configuration for the chamber 26 and includes a functional block diagram for an example of an exhaust system 95. Thus, as shown in FIG. 2, the carrier gas is introduced into the chamber 26 through an aperture in the collector 30 as indicated by arrow A. The carrier gas flows through the irradiation region 28 and the interior volume of chamber 26, in the process mixing with and carrying target material irradiation byproducts, e.g., tin vapor. The flow of the mixture of carrier gas and tin vapor is indicated by the arrows B.

The mixture of the carrier gas and tin vapor is evacuated from the chamber 26 by the exhaust system 95. The exhaust system 95 includes a scrubber or cleaner 100 that separates the tin vapor from the carrier gas. The scrubbed carrier gas flows through a gas cooler 120 and through a conduit 130 to vacuum pump 140. This is indicated by the arrow C.

As used herein, the term “scrubber” is intended to refer broadly to any components or combination of components that remove target material irradiation byproducts from a stream of gas flowing over or through the component or combination of components. This includes, for example, components specifically designed and intended for byproduct removal as well as surfaces such as the interior surfaces of conduits, piping, or the like that capture byproducts from a gas flowing over them.

Within the scrubber 100, the tin capture surfaces are in general heated so that the tin which has collected on the interior surfaces of the scrubber 100 melts or remains molten, detaches from those surfaces, and drains through a conduit 150 to a target material receptacle, also known as a tin bucket, 160 as indicated by the arrow D. The scrubber 100 removes the target material vapor from the gas mixture evacuated from the chamber 26 to protect the vacuum pump 140 (which may be more than one vacuum pump) and other exhaust hardware components that are sensitive to target material contamination.

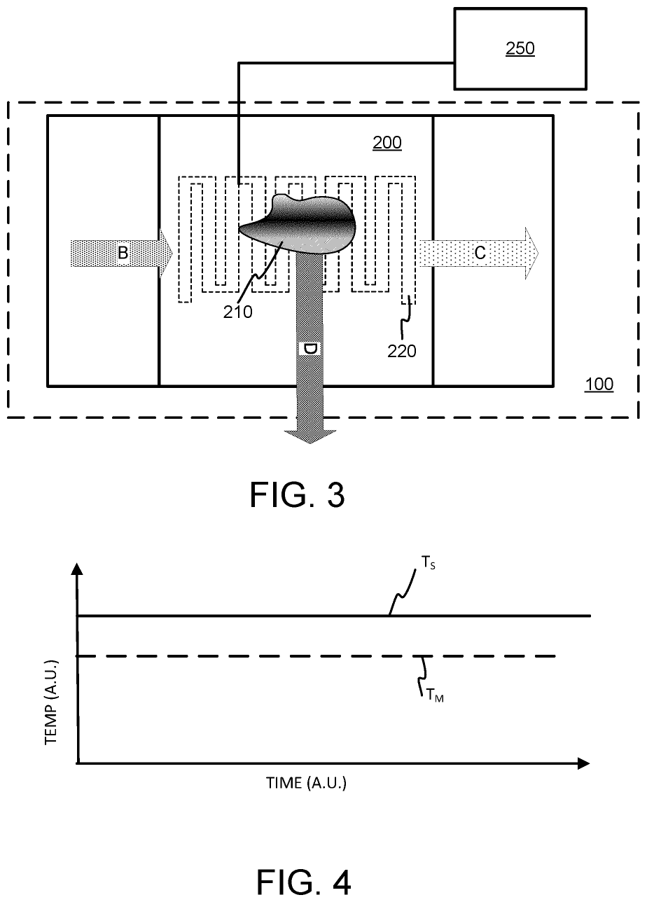

FIG. 3 shows an example of an arrangement such as that described. A surface 200 is located in the scrubber 100. It will be appreciated that the surface 200 could also be located at any other position at which a drip-off surface might be advantageously employed such as other surfaces in the exhaust system or on interior surfaces in the vessel. In the arrangement shown in FIG. 3 the gas mixture enters the scrubber 100 and passes over the surface 200. This is indicated by the arrow B. The carrier gas from which the vapor has been removed exits the scrubber 100 as indicated by the arrow C. While flowing over and onto the surface 200, the target material deposits as a volume 210 of target material. The volume 210 of target material accumulates and grows and will increasingly obstruct the flow of gas through the scrubber 100 unless provision is made for its removal.

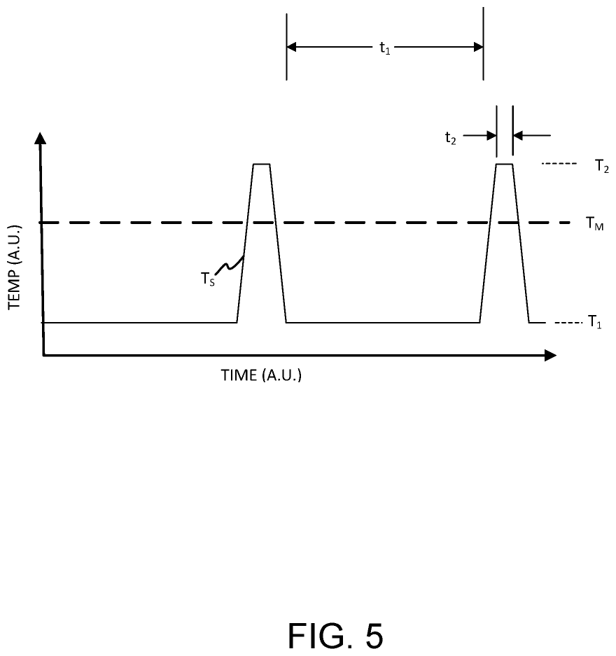

Towards this end, the surface 200 is placed in thermal communication or contact with a heating element 220. Here and elsewhere herein, two objects are in “thermal communication” or “thermal contact” if there is a direct or an indirect path for heat flow between them. In the example shown thermal energy from the heating element 220 continuously maintains the temperature of the surface 200 at a temperature above the melting temperature of the target material. This is shown in FIG. 4, which is a graph of the temperature T_{S} of the surface 200 versus time while the EUV radiation source is being operated. As shown, the temperature T_{S} is maintained at a level above the melting temperature T_{M} of the target material.

In the case where the target material is tin, then the melting temperature is 232 °C (449 °F or 505 K). In cases where the target material is not a pure metal references to the melting temperature are intended to refer to the liquidus temperature, i.e., the lowest temperature at which the accumulated target material is completely liquid.

The heating element 220 is connected to a control system 250 which supplies power to the heating element 220. In the arrangement shown in FIG. 3, the heating element 220 is shown in phantom because it is located behind the surface 220 with respect to the viewing angle of the figure. One of ordinary skill in the art will appreciate that the heating element 220 may be placed at other positions. One of ordinary skill in the art will also appreciate that there may be more than one heating element. The heating element 220 is depicted as being serpentine but other arrangements can be used. In the example shown the heating element 220 is an electric resistive heater, but other types of heating elements may be used. Due to the heating of the surface 200, the target material becomes or remains liquid and flows out of the scrubber 100 as indicated by the arrow D.

The design and operation of the scrubber is influenced by several competing design goals. One such design goal is high scrubbing efficiency. A high scrubbing efficiency (in terms of amount of removal of target material irradiation byproducts deposited from the carrier gas/target material mixture) is desired in order to protect the exhaust system hardware components from target material contamination. Another design goal is to maintain a low pressure drop across the scrubber. A low pressure drop is desired in order to enable EUV radiation source operation at a low vessel pressure to maximize EUV transmission through the EUV radiation source vessel.

The design of the target material scrubber or cleaner thus involves an engineering tradeoff in that high scrubbing efficiency and low pressure drop are competing requirements when the volume allocated to the scrubber is limited, because both scrubbing efficiency and the pressure drop increase with the scrubber surface area.

Another competing design goal is minimization of the target material spitting rate, that is, the rate of ejection of microparticles from the target material that has accumulated on the scrubber surfaces. A low spitting rate is desired in order to protect the interior surfaces of the vessel and exhaust system components from target material that ejects from the scrubber. The spitting rate can be suppressed by maintaining the surface at a temperature below the target material melting point, a temperature range in which spitting is eliminated and the pressure drop is lowest. This, however, permits the target material collected on the surfaces to build up and clog the flow path through the exhaust system over time. This increases vessel pressure which in turn adversely affects EUV transmission through the vessel.

Thus the design of target material scrubbers must balance scrubbing efficiency and pressure drop within an allocated volume. Also, as shown in FIG. 4, the scrubber surfaces are in general maintained at a temperature above the target material melting point continuously during operation of the EUV radiation source in order to permit target material to remain molten so that it can drain to prevent clogging, but at the expense of increased spitting and increased pressure drop.

Future EUV radiation sources will impose even more stringent demands on scrubber design. In particular, future EUV radiation sources will require less spitting (to reduce EUV radiation source, scanner, and exhaust system contamination) and operate at a higher target material load (to increase EUV power) and at a higher H2 gas flow rate (to better protect EUV collection optics and the vessel walls at increased EUV power). Meeting these demands will further complicate the task of maintaining high scrubbing efficiency with a low pressure drop and a low spitting rate.

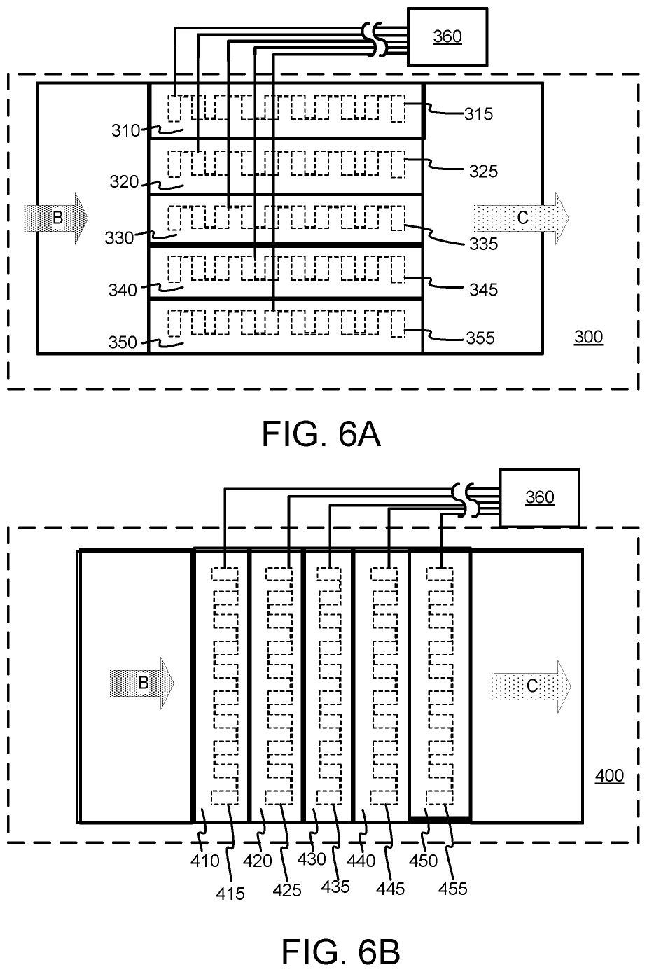

According to an embodiment, one measure to improve spitting performance while reducing the pressure drop between the chamber and the vacuum pump entails thermally cycling the scrubber surfaces. In other words, rather than continuously maintaining the temperature T_{S} of a given scrubber surface at or above the melting temperature T_{M} of the target material while the source is in operation, the temperature T_{S} of the surface can be cycled between a first state in which it is maintained at a first temperature Ti below the target material melting point T_{M} for a first time interval t₁ as shown in FIG. 5, thus permitting the target material to solidify on the surface. Periodically or as it is determined to be necessary or desirable the temperature T_{S} of the surface may be increased to a second temperature T₂ above T_{M} for a second interval t₂. The temperature of the scrubber surface can then revert to T₁ after the scrubber surface has been sufficiently cleared of accumulated target material. This process may be performed repeatedly.

In one embodiment, the values for t₁, t₂, T₁, and T₂ are predetermined either by calculation or empirically. For some implementations it will be desirable to maintain the higher temperature T₂ above and as close as practical to the melting temperature of the target material in order to minimize the target material re-emission (spitting) rate, which increases with temperature. For some implementations it will be desirable to maintain the lower temperature T₁ below and as far away from the melting temperature of the target material as possible, in order to eliminate spitting and to also minimize pressure drop. In some embodiments it is desirable that the time-averaged temperature of the surface be below the melting temperature of the target material.

As regards the duration for each temperature, target material drip-off can be expected to occur as soon as the temperature T_{S} of the scrubber surface is above the melting temperature of the target material over the entire area of the surface. It typically takes less than about 30 minutes for the one or more heating elements arranged to heat the surface to do so to above the melting temperature of tin. The duration over which accumulation in cold operation can be tolerated depends on the scrubber geometry and the trade-off between pressure drop and scrubbing efficiency. As one example, the duration t₂ at the high temperature T₂ may be about one hour every 24 hours with drip-off being performed about once every 24 hours making the duration t₁ at the low temperature T₁ about 23 hours.

Thus, when the temperature of the scrubbing surface is maintained below the melting temperature of the target material, the volume of the target material deposits on the scrubbing surface will grow and increasingly block or at least restrict, the flow of gas. Once the volume of target material deposits, or the amount of flow restriction, reaches a specified level, as measured or assumed from, for example, the passage of operating time, the temperature of the scrubbing surface is increased to a temperature above the melting temperature of the target material to cause at least some of the volume of target material deposits on the scrubbing surface to melt and flow away from the scrubbing surface to reduce the volume of target material deposits on the scrubbing surface. After a volume of target material deposits remaining on the scrubbing surface has been reduced below a second amount, and so causing a lesser degree of exhaust path restriction, again as measured or as may be inferred from, for example, and amount of heating time, heating of the scrubbing surface is discontinued so that the scrubbing surface again assumes a temperature below the melting temperature of the target material.

The process just described can be run continuously or be initiated periodically or on an as-needed basis, with need being determined from running time or some measured operational parameter such as a predetermined amount of increase in the pressure drop across the scrubber or an amount of increase in the pressure in the chamber 26.

Thermally cycling the scrubber surfaces as just described has the potential to reduce spitting because spitting does not occur when the target material is solid. It can at the same time improve the pressure drop between the chamber interior and the vacuum pumps because the pressure drop is proportional to gas viscosity which in turn is inversely proportional to temperature. During the heat cycle to promote target material drip-off, however, the pressure drop temporarily increases to levels higher than those reached during continuously heated operation due to the accumulation of target material. This causes a temporary increase in pressure in the EUV radiation source vessel which reduces EUV transmission through the vessel, which in turn causes unwanted process variation. This process variation can be avoided by shutting down the source during the heat cycle but this could reduce system availability to unacceptable levels.

According to another aspect of an embodiment a multizone target material accumulation surface thermal control and drip-off arrangement and procedure is implemented that enables improved performance without causing unacceptable high levels of process variation. According to this multizone arrangement and procedure, an accumulation surface such as that in the scrubber is divided into multiple sections or zones, with each of the zones being respectively in thermal communication with its own respective and independently controllable one or more heating elements. The heating elements are controlled in such a way that not all of, i.e., only a subset of, the heating elements heat their respective zones above the target material melting temperature at any given time. For example, the zones can be sequentially heated one at a time with adjacent zones being heated in a set sequence which is repeated periodically while the source is in operation. This, however, is just an example. Neighboring zones do not necessarily need to be heat-cycled one after the other. Any sequence of zone heating and drip-off will work, as long as all zones undergo a drip-off procedure before they accumulate too much tin.

In other words, a target material accumulation surface heat control and drip-off arrangement and procedure is implemented, in accordance with an aspect of an embodiment, to enable increased performance without creating unacceptable high levels of process variation. The heating elements are controlled so that just a portion of them, or a subset of them, are ever heating their respective zones above the melting point of the target material. For instance, the zones can be heated one at a time, with the next zone to be heated being adjacent the zone being heated.

References herein to the surface being divided into zones or sections are not necessarily intended to mean that the surface is physically so divided. The surface need not be physically divided to be divided into zones. It is only preferred that the zones be thermally distinct, that is, the zones may be brought to and maintained at different temperatures.

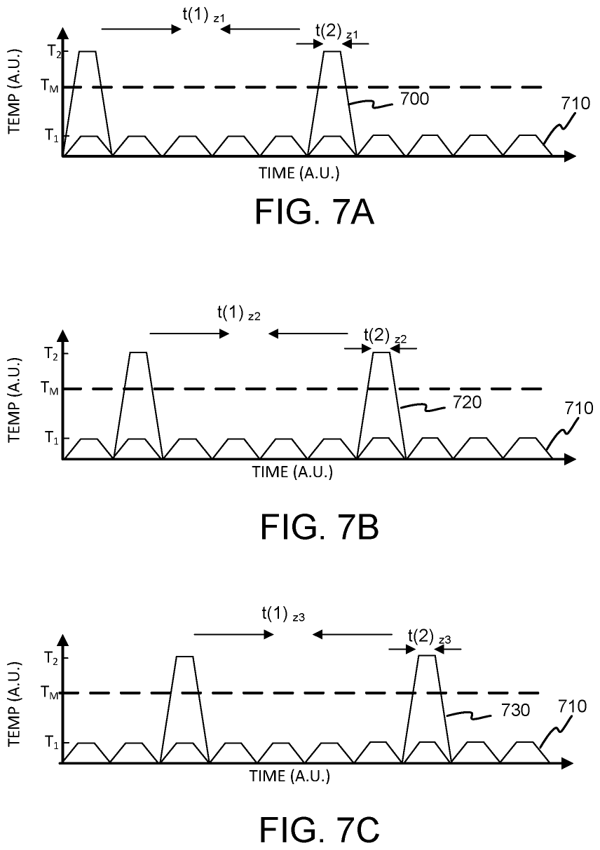

FIG. 6A is a diagram of a surface in a scrubber 300 which is partially divided into a linear array of zones. In the example shown in FIG. 6A there are five zones but one of ordinary skill in the art will appreciate that there could be fewer or more zones depending on the design considerations of a given application. The five zones in the embodiment of FIG. 6A are numbered 310, 320, 330, 340, and 350, respectively. In the embodiment of FIG. 6A the zones are oriented to have a long dimension parallel to the direction of the flow of the mixture of carrier gas and vapor through the scrubber 300 as indicated by the arrow labeled B. Each of these zones has associated with it a respective heating element 315, 325, 335, 345, and 355. The individual heating elements are under separate control of a controller 360. In the arrangement shown in FIG. 6A, each of the zones may be maintained at a different temperature either above or below the melting temperature of the target material. The gas mixture flows over the surface, depositing target material onto the surface in the process. Then the carrier gas, from which the target material vapor has been removed, leaves the scrubber 300 as indicated by the arrow C.

Here and in all embodiments, it will be understood that each zone may have more than one heating element associated with it. For example, it is possible in some embodiments that each zone may have one heating element that is heated continuously to maintain the temperature of the zone at the lower temperature below the melting temperature of the target material with a second heating element being heated as needed to increase the temperature of the zone from the lower temperature to the higher temperature above the melting temperature of the target material. Thus the controller is operable to cycle the zones between the lower temperature and the higher temperature.

FIG. 6B shows an arrangement similar to that of FIG. 6A except that the surface in the scrubber 400 is divided into individual zones 410, 420, 430, 440, and 450 respectively, that are oriented to have their short dimension parallel to the flow of the gas mixture over the surface. Each of the zones has at least one associated heating element 415, 425, 435, 445, and 455, respectively. These heating elements are individually controllable by the controller 360.

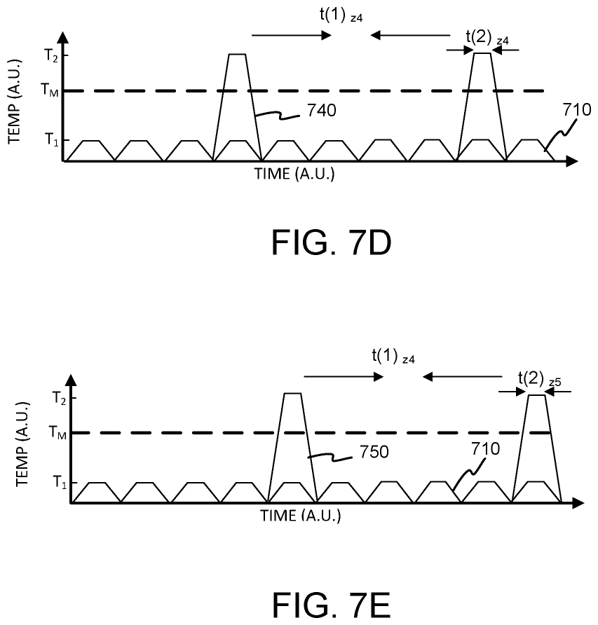

Heating elements in the arrangements described above are individually controllable according to any one of a number of possible patterns. FIGS. 7A through 7E show one such control pattern. FIG. 7A shows a graph 700 of temperature versus time for the first zone 310 of the arrangement of FIG. 6A or 6B. As can be seen, the temperature of the first zone is raised from a temperature T₁ which is below the melting temperature T_{M} of the target material to a second temperature T₂ which is above T_{M}. The temperature of the first zone is then permitted to drop below T_{M} back down to T₁. The first zone is at the temperature T₁ for an interval t(1)_{z1} and at the second temperature T₂ for an interval t(2)_{z1}. FIG. 7A also shows a graph 710 of the time average temperature of the surface as a function of time. As can be seen, in an embodiment the time average of the overall surface temperature is maintained below T_{M.}

FIG. 7B shows a graph 720 of temperature versus time for the second zone 320 of the arrangement of FIG. 6A or 6B. The time scales of the graph 700 and the graph 720 are aligned as are the time scales in all of the graphs in FIGS. 7A-7E. As can be seen, after the temperature of the first zone is controlled to be T₁, the temperature of the second zone is raised from T1, which is below T_{M}, to T₂ which is above T_{M}. The temperature of the second zone is then permitted to drop below T_{M} back down to T₁. The second zone is at the first temperature T₁ for an interval t(1)_{z2} and at the second temperature T₂ for an interval t(2)_{z2}. FIG. 7B also shows the graph 710 of the average temperature across all zones of the surface as a function of time, as do all of the graphs in FIGS. 7A-7E.

FIG. 7C shows a graph 730 of temperature versus time for the third zone 330 of the arrangement of FIG. 6A or 6B. As can be seen, after the temperature of the second zone is controlled to be T₁, the temperature of the third zone is raised from T1 to T₂. The temperature of the third zone is then permitted to drop back down to T₁. The third zone is at the first temperature T₁ for an interval t(1)_{z3} and at the second temperature T₂ for an interval t(2)_{z3}.

FIG. 7D shows a graph 740 of temperature versus time for the fourth zone 340 of the arrangement of FIG. 6A or 6B. Similar to what is described above, after the temperature of the third zone is controlled to be T₁, the temperature of the fourth zone is raised from T₁ to T₂. The temperature of the fourth zone is then permitted to drop back down to T₁. The fourth zone is at the first temperature T₁ for an interval t(1)_{z4} and at the second temperature T₂ for an interval t(2)_{z4}.

FIG. 7E shows a graph 750 of temperature versus time for the fifth zone 350 of the arrangement of FIG. 6A or 6B. As can be seen, after the temperature of the fourth zone is controlled to be T₁, the temperature of the fifth zone is raised from T₁ to T₂. The temperature of the fifth zone is then permitted to drop back down to T₁. The fifth zone is at the first temperature T₁ for an interval t(1)z5 and at the second temperature T₂ for an interval t(2)_{z5}.

One of ordinary skill in the art will appreciate that the temperature ramp up and ramp down as shown in FIGS. 7A through 7E represent just two nonlimiting examples of how the temperature may be increased or decreased. For example, the temperature ramp up and ramp down are shown as having a linear dependence on time. One of ordinary skill in the art will appreciate that some other nonlinear functional dependence on time can be used. Also, in the nonlimiting example the temperature ramp up and ramp down are antisymmetric in the sense that the slope of one is negative the slope of the other and that the onset and end of both the increase and the decrease are synchronized. Again, this is simply an example and one of ordinary skill in the art will appreciate that relationships between the temperature increase and decrease that are not antisymmetric may be used.

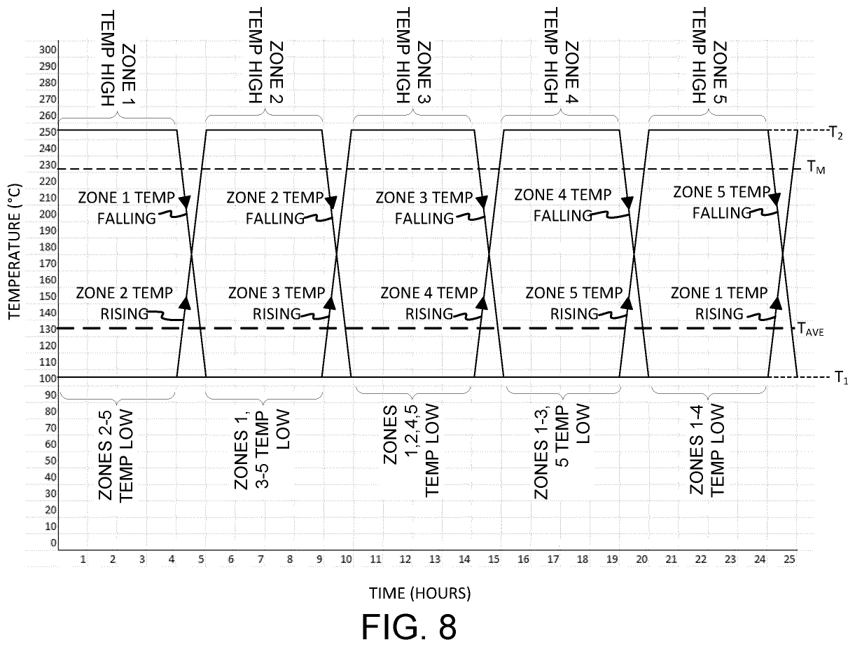

In some implementations it may be desirable to maintain the zone average temperature relatively constant over an entire heating cycle. FIG. 8 is a graph of temperature versus time for a five zone arrangement. As before, five zones are used simply as an example. It will be apparent to one of ordinary skill in the art that fewer zones or more zones could be used.

As shown in FIG. 8, during a first (leftmost) interval zone 1 is held at its high temperature T₂ while the remaining zones 2-5 are held at their low temperature T₁. In this example, the high temperature T₂ is chosen to be slightly above the melting temperature T_{M} of the target material. In the example shown, in which the target material is tin, the melting temperature T_{M} is 232 °C. The high temperature T₂ is chosen to be 250 °C. The low temperature T₁ is selected to be 100 °C. This gives a running average temperature TAVE (i.e., an average running with time) across the zones of 130 °C which remains relatively constant as the remaining zones are sequentially heated.

Thus, in the next interval to the right, zone 2 is heated to its high temperature while zones 1-3 and 5 are at their low temperature. In the next interval, zone 3 is heated to its high temperature while zones 1, 2, 4, and 5 are heated to their low temperature. In the next interval, zone 4 is heated to its high temperature while zones 1-3 and 5 are maintained at their low temperature. In the next interval zone 5 is heated to its high temperature while zones 1-4 are maintained at their low temperature. The cycle then recommences.

Every zone is held at its high temperature for approximately four hours and at its low temperature for 19 hours during a 25 hour cycle, with an additional two hours at transitional temperatures while the temperature is either falling or rising.

These temperatures and durations are just examples. For this embodiment the use of other values is possible as long as the temperatures and durations are selected so that the time variation of the average temperature of the multizone surface taken across all zones is minimized.

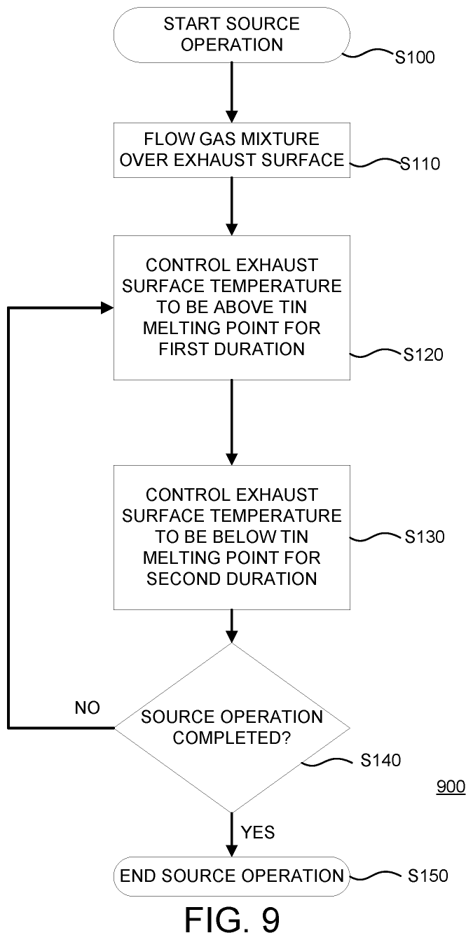

FIG. 9 is a flow chart of a process 900 for managing target material in an EUV radiation source according to an aspect of an embodiment. In a step S100 the operation of the source is started. In a step S110 a mixture of carrier gas and target material vapor is caused to flow over a surface such as an exhaust system of the source, e.g., a scrubbing surface of a scrubber or an exhaust surface outside of the scrubber. In a step S120 the temperature of the exhaust surface is controlled to be above the target material melting point for a first duration, with tin being used as an example of a target material. In a step S130 the temperature of the exhaust surface is controlled to be below the melting point of tin for a second duration. Then, in a step as 140, if the source is still being operated, the process reverts to step S120 and the temperature of the exhaust surface is again controlled to be above the melting point for tin for the first duration. Otherwise, in step S140, operation of the source is discontinued.

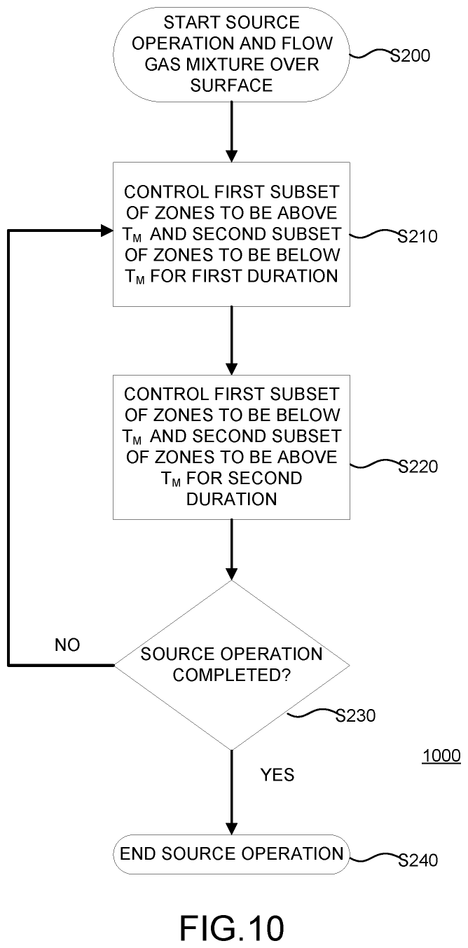

FIG. 10 is a flow chart of a process 1000 for controlling the temperature profile of a surface in an exhaust system of an EUV radiation source according to an aspect of an embodiment. In step S200 operation of the source commences and a mixture of carrier gas and target material vapor is caused to flow over the surface. In a step S210 the temperature of the surface is controlled such that a first subset of zones is at a temperature above T_{M}, the melting temperature of the target material, while a second subset of zones is controlled to be below T_{M}. Then, in a step S220, the temperature of the surface is controlled so that the temperature of the first subset of zones is below T_{M} and the second subset of zones is above T_{M}.

Then in a step S230 is determined whether operation of the source is completed. If not, then the process reverts to step S210. If it is determined in step S230, however, that operation the source is completed, then in the step S240 operation of the source is discontinued.

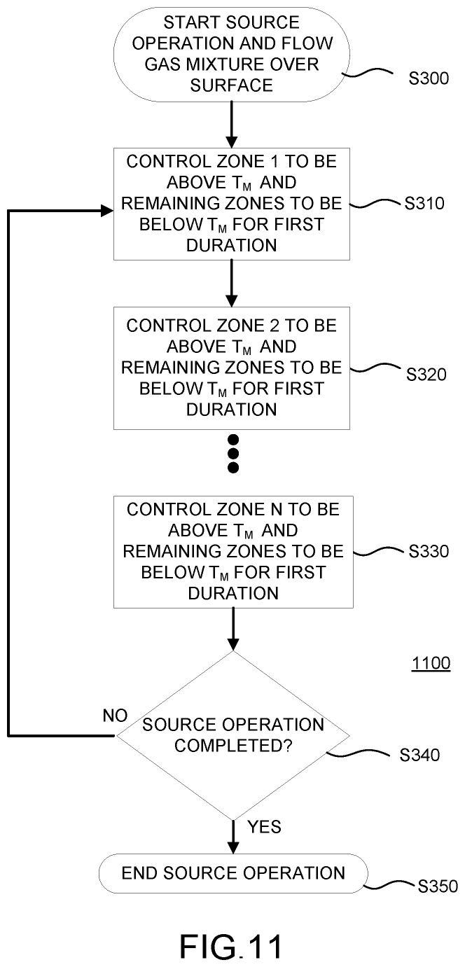

FIG. 11 is a flow chart of a process 1100 for controlling the temperature profile of a surface such in an EUV radiation source as a surface in an exhaust system according to an aspect of an embodiment. In step S300 operation of the source commences and a mixture of carrier gas and target material vapor is caused to flow over the surface. In a step S310 the temperature of a first zone of the exhaust surface is controlled to be above T_{M} while a temperature of at least some of the remaining zones is controlled to be below T_{M}. In the example shown, a temperature of all of the remaining zones is controlled to be below T_{M}. Then, in a step S320, the temperature of a second zone of the surface is controlled to be above T_{M} while a temperature of at least some of the remaining zones is controlled to be below T_{M}. This process continues zone-by-zone until the Nth zone is heated above T_{M} with the temperature of at least some of the remaining zones being controlled to be below T_{M} in step S330. Then in a step S340 is determined whether operation of the source is completed. If not, then the process reverts to step S310. If it is determined in step S340, however, that operation the source is completed, then in the step S350 operation of the source is discontinued.

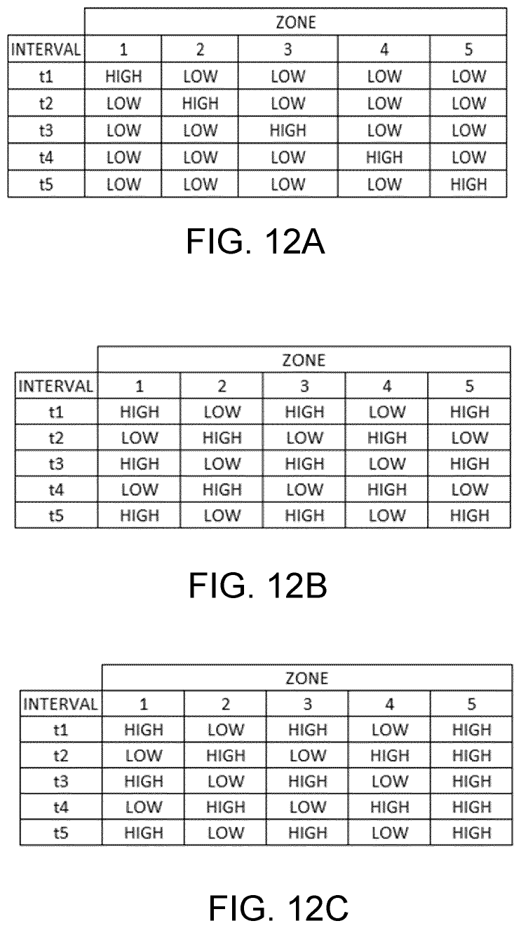

FIGS. 7A-7E and 8 relate to examples in which the high/low heating pattern for the zones is established such that only one zone is at its high temperature at a given time. FIG. 12A is a chart describing this pattern in which t1, t2, and so on are sequential time intervals, “high” refers to a temperature above the melting temperature of the target material, and “low” refers to a temperature below the melting temperature of the target material. One of ordinary skill in the art will understand that other patterns are possible. For example, a high/low heating pattern for the zones could alternate in each time interval as shown in the chart in FIG. 12B. Also, it is possible that one zone could be constantly maintained at a given temperature such as the high temperature, as is the case for zone 5 in FIG. 12C. A pattern such as that shown in FIG. 12C could be useful, for example, for zones that are farther downstream from the chamber 26 so that any spitting that occurs in that zone is less likely to reach the EUV collection optics.

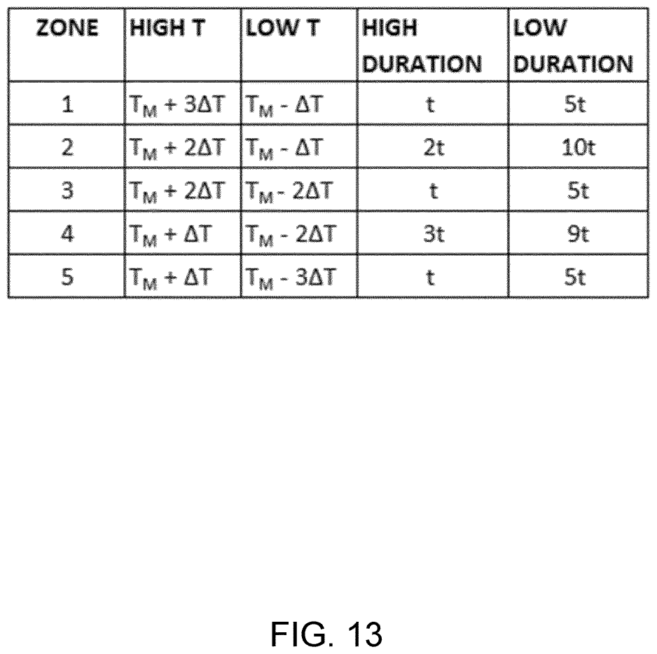

Also, in the embodiment described in connection with FIGS. 7A-7E, the respective high and low temperatures and the time intervals for those temperatures are shown as being the same for every zone. This is simply an example. It will be apparent to one of ordinary skill in the art that the high and low temperatures for each zone could be different from one another as well as the respective time intervals at those temperatures. FIG. 13 is a chart showing an example of other possible values for high temperatures, low temperatures, and durations in an arrangement having five zones. For example, for zone 1, the high temperature could be positive offset from T_{M}, the melting temperature of the target material, of 3ΔT where ΔT is some fixed number of degrees. The low temperature could be a negative offset from T_{M} of simply ΔT. The duration for the high temperature for zone 1 could be a value t and the duration for which zone 1 is controlled to be at its low temperature could be a multiple of t such as 5t. One of ordinary skill in the art will appreciate that other values are possible. The duration times can be selected so that there is no overlap between times when zones are being controlled to their high temperature or arrangements in which there is some overlap.

As mentioned, according to another aspect of an embodiment the thermal control and drip-off procedure is implemented in such a way that a time-averaged temperature of the entire ensemble of zones is below the target material melting temperature and so below the time-averaged temperature of a design in which a single zone surface is continuously maintained at above the melting temperature of the target material. This minimizes spitting and reduces the pressure drop across a scrubber in which the surface is located.

Also according to an aspect of an embodiment, the high temperature, low temperature, and duration at each are selected such that the zone-averaged peak temperature is lower than in a heat-cycled configuration for a single zone surface. This reduces process variation because it reduces pressure disturbances in the EUV radiation source vessel.

The multizone temperature control system described above also permits an improvement in scrubbing efficiency because some of the potential improvement in pressure drop can be traded for improvement in scrubbing efficiency by increasing the area of the scrubbing surface.

As noted above, the number of zones and their respective heating patterns can be optimized to minimize pressure drop and process variation. The zones may be heated cyclically, that is, first a first zone, then a second zone adjacent the first zone, then a third zone adjacent the second zone, and so on until all of the zones have been heated in turn, at which point the first zone is heated again and the process repeats.

As noted, the applicability of the heating procedure is not limited to exhaust system surfaces located within the scrubber. The heating procedure is also applicable to surfaces in the exhaust system that are located outside of the scrubber.

Also, the foregoing description is primarily in terms of applying a multizone drip-off system and procedure to surfaces in an exhaust system of an EUV source resulting in several benefits including minimization of process variation via elimination of a temporary very high pressure drop penalty which would otherwise be incurred by the use of a contaminated scrubber. A multizone drip-off procedure may also be advantageously employed in other parts of the EUV source including structures in the vessel such as the vessel walls. The use of a multizone drip-off procedure in the vessel has the potential to help minimize process variation via elimination of gas temperature change which reduces EUV gas transmission variation, or to help achieve reduced local maximum temperatures which are above but very close to target material melting temperature during drip-off, i.e., the temperature at which the spitting rate of molten tin is lowest, or to help guide molten target material along a preferred the path during drip-off.

Some of the above description is in terms of functional block diagrams with some functions allocated to some blocks and other functions allocated to other blocks. It will be understood that the divisions between blocks and the allocations are arbitrary and that different divisions and allocations are possible so long as the overall functions are carried out as described above.

The above description includes examples of multiple embodiments. It is, of course, not possible to describe every conceivable combination of components or methodologies for each of these embodiments, but one of ordinary skill in the art may recognize that many further combinations and permutations of elements of the various embodiments are possible based on the disclosure. Accordingly, the described embodiments are intended to be representative of and encompass all such alterations, modifications, and variations that fall within the spirit and scope of the appended claims.

Furthermore, to the extent that the term “includes” is used in either the detailed description or the claims, such term is intended to be inclusive in a manner similar to the term “comprising” as “comprising” is construed when employed as a transitional word in a claim. Also, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract, and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract, and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added.

Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not necessarily include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, or 0.1 degree.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as nonexclusive.

The embodiments can be further described using the following clauses:
1. A system for management of a target material in an extreme ultraviolet radiation source, the system comprising:
   at least one surface arranged such that a carrier gas entraining target material vapor and debris flows over the surface thus leaving deposited target material on the surface;
   at least one heating element in thermal communication with the at least one surface; and
   a controller configured to control the at least one heating element to cycle the at least one heating element between a first state in which a temperature of the at least one surface is above a melting temperature of the target material and a second state in which a temperature of the at least one surface is below the melting temperature of the target material.
2. The system as in clause 1 wherein the at least one surface comprises a surface in an exhaust system for the extreme ultraviolet radiation source.
3. The system as in clause 2 wherein the at least one surface comprises a surface in a scrubber.
4. The system as in clause 2 wherein the exhaust system includes a scrubber and wherein the at least one surface is positioned outside of the scrubber with respect to a flow of the carrier gas entraining the vapor.
5. The system as in clause 1 wherein the at least one surface comprises a surface in a vacuum vessel for the extreme ultraviolet radiation source.
6. The system as in clause 1 wherein the target material comprises tin.
7. The system as in clause 1 wherein the carrier gas comprises molecular hydrogen.
8. A system for management of a target material in an extreme ultraviolet radiation source, the system comprising:
   at least one surface arranged such that a carrier gas entraining target material vapor and debris flows over the surface thus leaving deposited target material on the surface, the surface having at least a first zone and a second zone;
   a first heating element in thermal communication with the first zone;
   a second heating element in thermal communication with the second zone; and
   a controller configured to control the first heating element and the second heating element to cycle between a first state in which a temperature of the first zone is above a melting temperature of the target material and the temperature of the second zone is below a melting temperature of the target material and a second state in which a temperature of the first zone is below the melting temperature of the target material and the temperature of the second zone is above the melting temperature of the target material.
9. The system as in clause 8 wherein the at least one surface comprises a surface in an exhaust system for the extreme ultraviolet radiation source.
10. The system as in clause 9 wherein the at least one surface comprises a surface in a scrubber.
11. The system as in clause 9 wherein the exhaust system includes a scrubber and wherein the at least one surface is positioned upstream of the scrubber with respect to a flow of the carrier gas entraining the vapor.
12. The system as in clause 8 wherein the at least one surface comprises a surface in a vacuum vessel for the extreme ultraviolet radiation source.
13. The system as in clause 8 wherein the target material comprises tin.
14. The system as in clause 8 wherein the carrier gas comprises molecular hydrogen.
15. The system as in clause 8 wherein the controller controls the first heating element and the second heating element to lessen a variation in a running average of the temperature of the first zone with the second zone.
16. A system for management of a target material in an extreme ultraviolet radiation source, the system comprising:
   at least one surface arranged such that a carrier gas entraining target material irradiation byproducts flows over the at least one surface thus depositing target material on the at least one surface, the at least one surface having a plurality of zones numbering N zones, N being a positive integer;
   a plurality of heating elements having at least N heating elements, each of the heating elements being in thermal communication with a respective one of the zones and each of the heating elements being controllable to heat its respective zone to a temperature above a melting temperature of the target material; and
   a controller configured to control each heating element in the plurality of heating elements such that only a subset of the zones numbering M zones is heated above the melting temperature of the target material at any time, M being an integer less than N.
17. The system as in clause 16 wherein N is five and M is one.
18. The system as in clause 16 wherein the plurality of zones is arranged as a linear array and wherein the controller is configured to control the heating elements to cyclically heat the zones.
19. The system as in clause 16 wherein the at least one surface comprises a surface in a scrubber.
20. The system as in clause 16 wherein the exhaust system includes a scrubber and wherein the at least one surface is positioned outside of the scrubber with respect to a flow of the carrier gas entraining the vapor.
21. The system as in clause 16 wherein the target material comprises tin.
22. The system as in clause 16 wherein the carrier gas comprises molecular hydrogen.
22. The system as in clause 16 wherein the controller controls each of the plurality of heating elements to lessen a variation in a running average of the temperature across the plurality of zones.
24. A method of operating a scrubbing surface to remove target material deposits, the method comprising:
   (a) maintaining the scrubbing surface at a first temperature below a melting temperature of the target material deposits to cause the target material deposits to accumulate on the scrubbing surface until a volume of target material deposits reaches a first amount causing a first degree of exhaust path restriction;
   (b) heating the scrubbing surface to a second temperature above the melting temperature of the target material deposits such that at least a portion of the volume of target material deposits on the scrubbing surface melts and flows away from the scrubbing surface to reduce the volume of target material deposits on the scrubbing surface; and
   (c) after a volume of target material deposits remaining on the scrubbing surface has been reduced below a second amount causing a second degree of exhaust path restriction, the second degree being less than the first degree, discontinuing heating the scrubbing surface to the second temperature and reverting to step (a).
25. The method as in clause 24, wherein the scrubbing surface has multiple zones that are independently temperature controlled, the method further comprising cycling a temperature of the zones to alternately increase and decrease the temperatures of different zones at different times.
26. A method of controlling target material accumulation in an extreme ultraviolet radiation source, the method comprising:
   flowing a mixture of a carrier gas and target material irradiation byproducts over at least one surface to deposit the target material on the surface; and
   controlling at least one heating element in thermal communication with the at least one surface to repeatedly cycle the at least one heating element between a first state in which a temperature of the at least one surface is above a melting temperature of the target material and a second state in which a temperature of the at least one surface is below the melting temperature of the target material.
27. A method as in clause 26 wherein controlling at least one heating element comprises controlling a first heating element in thermal communication with a first zone of the at least one surface and a second heating element in thermal communication with a first zone of the at least one surface to cycle between a first state in which a temperature of the first zone is above a melting temperature of the target material and the temperature of the second zone is below a melting temperature of the target material and a second state in which a temperature of the first zone is below the melting temperature of the target material and the temperature of the second zone is above the melting temperature of the target material.
28. A method of controlling target material accumulation in an extreme ultraviolet radiation source, the method comprising:
   flowing a mixture of a carrier gas and a target material vapor and debris over at least one surface to deposit the target material on a surface, the surface having a plurality of zones numbering N zones; and
   controlling each heating element of a plurality of heating elements having at least N heating elements each being in thermal communication with a respective one of the zones such that only a subset of the zones numbering M zones is heated above the melting temperature of the target material at any time, M being an integer less than N.

The above described implementations and other implementations are within the scope of the following claims.

1. A system for byproduct management in a radiation source,
the system comprising:
at least one surface arranged such that a carrier gas flow entraining metal vapor and debris flows over the surface;
at least one heating element in thermal communication with the at least one surface; and
a controller configured to control the at least one heating element to cycle the at least one heating element between a first state in which a temperature of the at least one surface is above a melting temperature of a metallic material of the debris and a second state in which a temperature of the at least one surface is below the melting temperature of the metallic material.

2. The system as in claim 1 wherein the at least one surface comprises a surface in an exhaust system for the radiation source.

3. The system as in claim 2 wherein the exhaust system includes a scrubber and wherein the at least one surface is positioned outside of the scrubber with respect to the carrier gas flow.

4. The system as in claim 1 wherein the at least one surface comprises a surface in a vacuum vessel for the radiation source.

5. The system as in claim 1 wherein the carrier gas flow comprises molecular hydrogen.

6. A system for byproduct management in an extreme ultraviolet radiation source, the system comprising:
at least one surface arranged such that a carrier gas flow entraining metal vapor and debris flows over the surface, the surface having at least a first zone and a second zone;
a first heating element in thermal communication with the first zone;
a second heating element in thermal communication with the second zone; and
a controller configured to control the first heating element and the second heating element to cycle between a first state in which a temperature of the first zone is above a melting temperature of a metallic material of the metal vapor and the temperature of the second zone is below a melting temperature of the metallic material and a second state in which a temperature of the first zone is below the melting temperature of the metallic material and the temperature of the second zone is above the melting temperature of the metallic material.

7. The system as in claim 6 wherein the at least one surface comprises a surface in a scrubber.

8. The system as in claim 6 wherein the at least one surface includes a surface in an exhaust system, the exhaust system includes a scrubber, and the at least one surface is positioned upstream of the scrubber with respect to the carrier gas flow.

9. The system as in claim 6 wherein the metallic metal includes tin.

10. The system as in claim 6 wherein the controller controls the first heating element and the second heating element in an alternating pattern.

11. A system for management of a target material in an extreme ultraviolet radiation source, the system comprising:
at least one surface arranged such that a carrier gas entraining target material irradiation byproducts flows over the at least one surface thus depositing target material on the at least one surface, the at least one surface having a plurality of zones numbering N zones, N being a positive integer;
a plurality of heating elements having at least N heating elements, each of the heating elements being in thermal communication with a respective one of the zones and each of the heating elements being controllable to heat its respective zone to a temperature above a melting temperature of the target material; and
a controller configured to control each heating element in the plurality of heating elements such that only a subset of the zones numbering M zones is heated above the melting temperature of the target material at any time, M being an integer less than N.

12. The system as in claim 11 wherein N is five and M is one.

13. The system as in claim 11 wherein the plurality of zones is arranged as a linear array and wherein the controller is configured to control the heating elements to cyclically heat the zones.

14. The system as in claim 11 wherein the at least one surface comprises a surface in a scrubber.

15. The system as in claim 11 wherein the exhaust system includes a scrubber and wherein the at least one surface is positioned outside of the scrubber with respect to a flow of the carrier gas entraining the vapor.

16. The system as in claim 11, wherein the controller controls each of the plurality of heating elements to lessen a variation in a running average of the temperature across the plurality of zones.

17. The system as in claim 11, wherein the plurality of zones is arranged along a direction in parallel with a flow of carrier gas.

18. The system as in claim 11, wherein the plurality of zones is arranged along a direction substantially perpendicular to a flow of carrier gas.

19. A method of operating a scrubbing surface to remove target material deposits, the method comprising:
(a) maintaining the scrubbing surface at a first temperature below a melting temperature of the target material to cause the target material deposits to accumulate on the scrubbing surface until a volume of target material deposits reaches a first amount causing a first degree of exhaust path restriction;
(b) heating the scrubbing surface to a second temperature above the melting temperature of the target material deposits such that at least a portion of the volume of target material deposits on the scrubbing surface melts and flows away from the scrubbing surface to reduce the volume of target material deposits on the scrubbing surface; and
(c) after a volume of target material deposits remaining on the scrubbing surface has been reduced below a second amount causing a second degree of exhaust path restriction, the second degree being less than the first degree, discontinuing heating the scrubbing surface to the second temperature and reverting to step (a).

20. The method as in claim 19, wherein the scrubbing surface has multiple zones that are independently temperature controlled, the method further comprising cycling a temperature of the zones to alternately increase and decrease the temperatures of different zones at different times.
